(19) United States
(12) Patent Application Publication
(10) Pub. No.: US 2007/0273388 A1
(43) Pub. Date: Nov. 29, 2007

(54) Load detection system (LDS)

(76) Inventor: Engne Tang, Lexington, MA (US)

Correspondence Address: Pandiscio & Pandiscio, P.C., 470 Totten Pond Road, Waltham, MA, 02451-1914, US

(21) Appl. No.: 10/743,605

(22) Filed: Dec. 22, 2003

Related U.S. Application Data
(60) Provisional application No. 60/435,886, filed on Dec. 21, 2002.

(51) Int. Cl. G01R 27/00

(52) U.S. Cl. 324/600; 434/350

(57) ABSTRACT

A load detection circuit for determining when (1) a loudspeaker load is properly connected at a set of loudspeaker terminals, (2) a loudspeaker load is improperly connected at the loudspeaker terminals, and (3) no loudspeaker load is connected at the loudspeaker terminals.

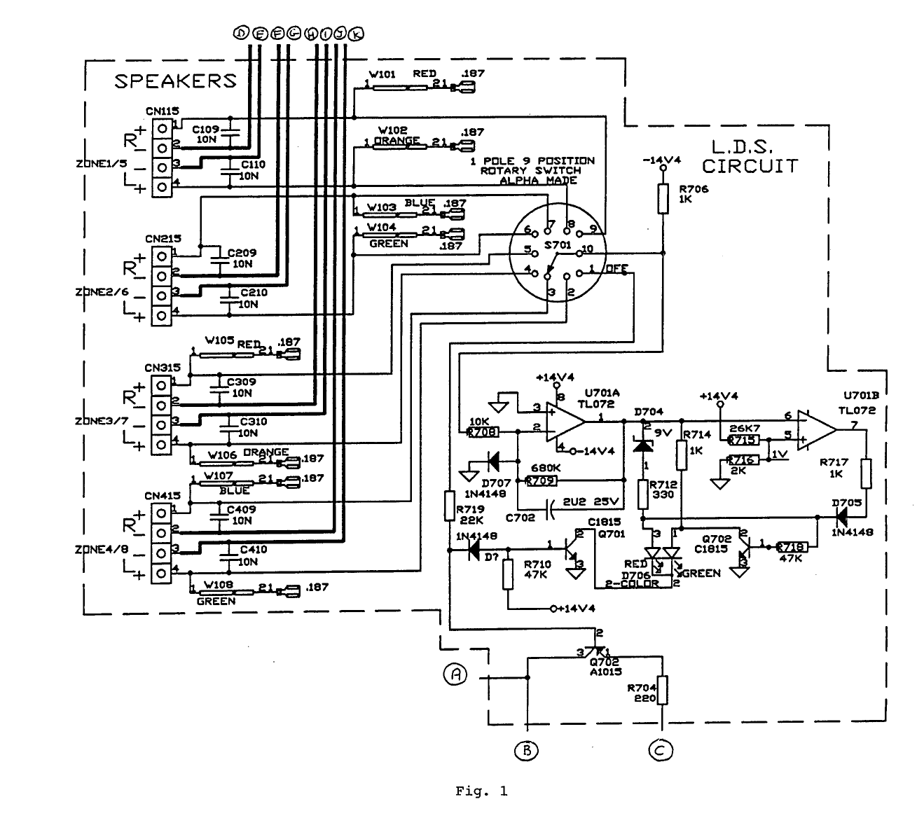

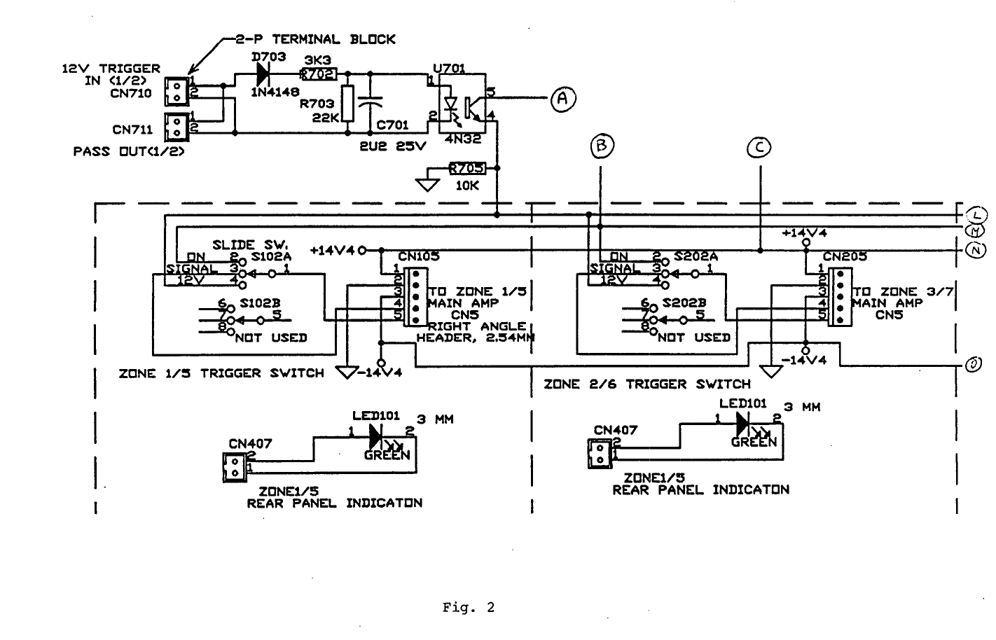

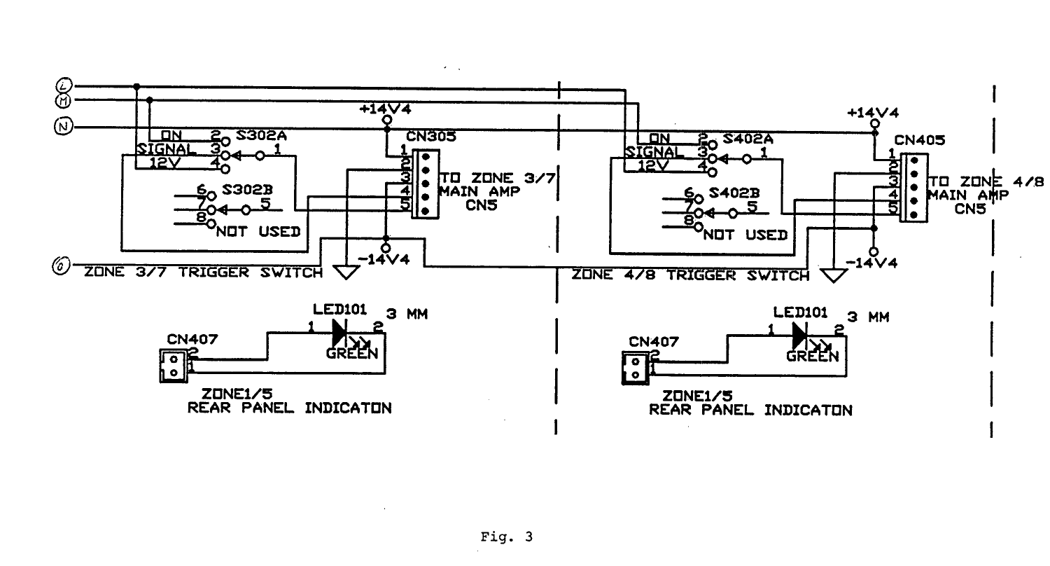

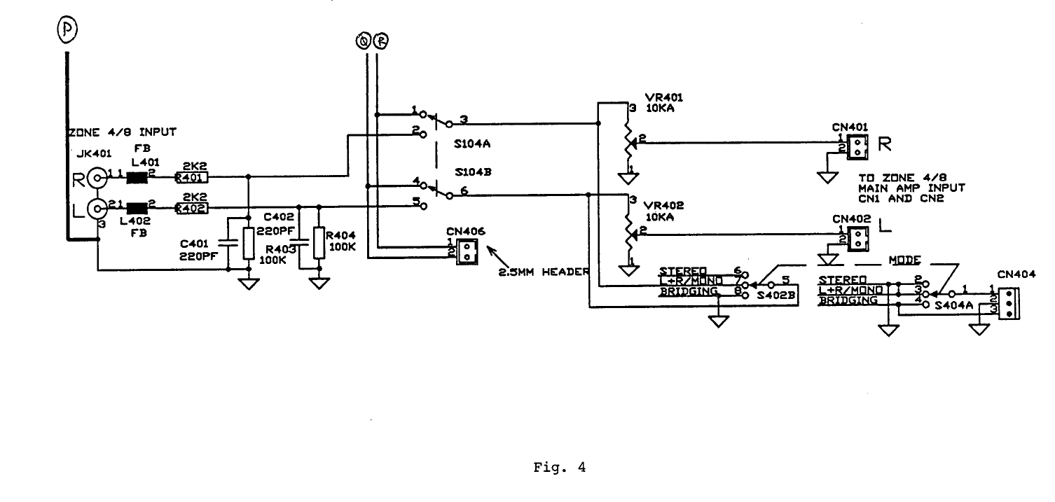

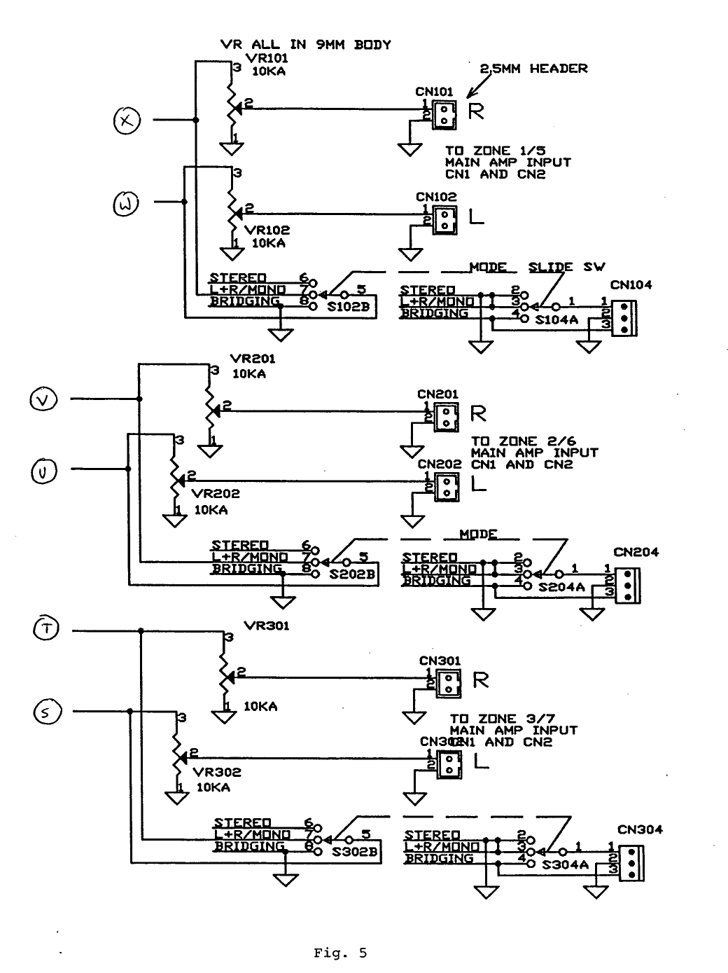

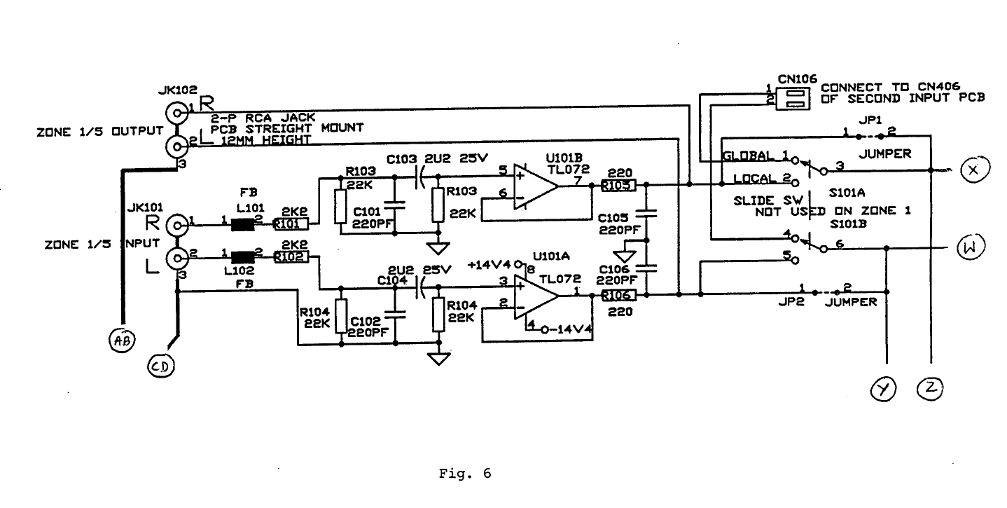

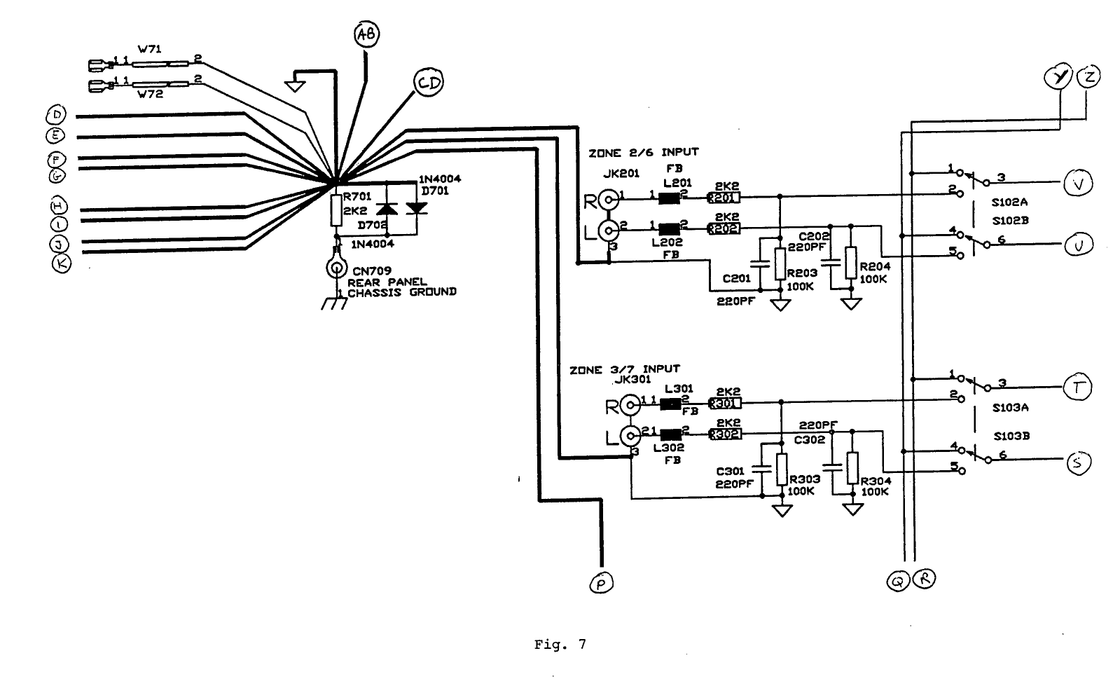

### REFERENCE TO PENDING PRIOR PATENT APPLICATION

This patent application claims benefit of pending prior U.S. Provisional Patent Application Ser. No. 60/435,886, filed Dec. 21, 2002 by Engne Tang for LOAD DETECTION SYSTEM (L.D.S.), which patent application is hereby incorporated herein by reference.

### FIELD OF THE INVENTION

This invention relates to audio systems in general, and more particularly to load detection systems for the same.

### DESCRIPTION OF THE INVENTION

The present invention comprises a load detection system (LDS) which permits loudspeaker connections to be thoroughly tested before the amplifier starts to play music.

Referring to the circuit diagrams, the heart of the LDS circuit consists of one dual-operational amplifier U701A and U701B, two transistors Q701 and Q702, one dual-color LED D706, and a few resistors and diodes.

The two operational amplifiers (opamps) are connected in two stages for different functions. The first stage is formed by U701A and its peripheral components R706, R708, R709, C702 and D707. It is configured as a linear DC amplifier with its gain of amplification set by the ratio between R709 and the parallel combined-resistance of R708, R706 and one of the speakers that the circuit is testing.

If a speaker is connected, as shown, to the R-channel speaker terminal CN415, it will be connected to the junction of R706 and R708 via the selecting switch S701. R708 is connected to the input pin 2 of opamp U701A. A speaker (with impedance ranging from 4 ohm to 8 ohm) with R706 forms a resistive divider that divides a DC voltage applied to the other end of R706. The voltage at the junction of R706 and R708 is determined by the divider. For R706 to be 1K ohm and a speaker to be 4 ohm, the dividing factor is 1000/4, or 250. The voltage at the junction of R706 and R708 is −14.4V/250=−0.0576V, or 58 mV. This voltage is amplified by U701A with a negative gain of −(R709/R708) or −68 times as with the values R706 and R708 shown. The pin 1 output of U701A will be (−0.0576V)×(−68), or +3.9V, this voltage will sometimes be referred to herein as the Normal Output Voltage. This output voltage at the U701A output is further used by the following stage formed by U701B and its peripheral components as will be described in paragraph [0009] below.

Similarly, if no speaker is connected at CN415, and S701 is selected to connect CN415 to the junction of R706 and R708, R708 will receive a full 14.4V DC voltage via R706. The output of U701A will be driven to the highest voltage U701A can provide, which is roughly equal to the negative DC power supply voltage +14.4V of the opamp. This output voltage is sometimes referred to herein as a High Output Voltage (which corresponds to an open-circuit or, that no speaker connection is made at speaker terminal CN415). This low output voltage at U701A output is further used by the following stage formed by U701B and its peripheral components as will be described in paragraph [0009] below.

In the same way, if a speaker is improperly connected so as to present a short circuit condition at CN415, and S701 is selected to connect CN415 to the junction of R706 and R708, the short-circuit will terminate the junction of R706 and R708 to ground potential. R708 receives no (zero) DC voltage via R706. The output of U701A will be zero volts. This output voltage is sometimes referred to herein as a Zero Output Voltage (which corresponds to a short-circuit wiring being made at CN415 speaker terminal). This zero output voltage at the U701A output is further used by the following stage formed by U701B and its peripheral components as will be described in paragraph [0009] below.

The second stage of the circuit formed by U701B and its peripheral components is a voltage comparator with two inputs. The first input pin is pin 6 of the opamp and the second input pin is pin 5 of the opamp. Pin 5 is biased by a resistive divider formed by R715 and R716 powered by 14.4 VDC supply voltage to set a reference. The divided voltage (reference) at pin 5 is 1.0V as shown with R715 being 26.7K ohm and R716 being 2K ohm. Comparator U701B will compare the two input voltages at its pin 5 and pin 6, if the input voltage at pin 6 is greater than the reference at pin 5 the output of U701B will produced a negative low output (−14.4V at pin 7). This output level at pin 7 of U701B is sometimes hereinafter referred as “−Vo”. If the input voltage at pin 6 of U701B is smaller than the reference at pin 5, the output of U701B goes to positive high output (+14.4V at pin 7), this output level at the output of U701B is sometimes hereinafter referred as “+Vo”. With the output of U701A connected to input pin 6 of U701B, any of the three possible output levels (i.e., Normal Output Voltage, High Output Voltage, and Zero Output Voltage) from the output pin 1 of U701A will be compared with the 1V reference (at pin 5) to produce only two levels (“+Vo” and “−Vo”) of outputs at pin 7 of U701B. In other words, if CN415 is connected with a normal speaker or with nothing, it produces a “−Vo” output at pin 7 of U701B; and if CN415 is connected in short-circuit condition, it produces a “+Vo” output.

The LED D706 is two light emitting diodes of two different colors (referred as color red and color green) packaged in the same housing. The device is use to generate 3 distinct colors, red, green, and red and green combined (amber).

The anode of the red part of LED D706 is connected via resistor R712 and zener diode D704 (9V) to the output pin 1 of opamp U701A, the anode of the red part of LED D706 is also connected via diode D705 and resistor R717 to the output pin 7 of opamp U701B. The red LED will be lit whenever the output pin 1 of U701A is higher than the sum of D704 zener diode voltage (9V) and the forward LED voltage (1.5V typically), or whenever the output pin 7 of U701B is higher than the sum of the D705 forward voltage (0.65V typically) and the LED forward voltage (1.5V)

In other words, the red LED will be lit if the output of U701A is in High Output Voltage condition, or whenever U701B output is “+Vo”. The red LED will be lit as long as there is an open-circuit (no connection) or a short-circuit made at speaker terminal CN415.

The anode of the green LED of D706 is connected to the output pin 1 of opamp U701A via resistor R714, also a NPN transistor Q702, with the collector connected to the anode of the green LED and the emitter to ground. Q702 is used to control the green LED to respond to the output states of U701B opamp output. The base of Q702 is driven by the output of U701B via diode D705 and resistor R717. When the output of U701B is in the “+Vo” state it turns Q702 into active state to bypass the the current of the green LED to ground, and when the output of U701B is in the “−Vo” state Q702 receives negative bias to stay in an off state. The green LED will be lit whenever the output voltage at pin 1 of U701A exceeds the LED forward voltage (1.5V typically), but only when transistor Q702 is in its off state which corresponds to a −Vo output at pin 7 of opamp U701B. In other words, the green LED will be lit as long as there is a open-circuit (no connection) or a normal speaker is connected at the speaker terminal CN415.

When combining the statements in the last sentences of the above two paragraphs, it can be said that the red and green LEDs will be lit together as long as there is a open-circuit (no connection) at the speaker terminal CN415. The red LED will be lit if and only if there is a short-circuit wiring made at the speaker terminal CN415. The green LED will be lit if and only if a normal speaker is connected at the speaker terminal CN415. In other words, when CN415 is shorted, the LED will be in red; when CN415 is not connected, the LED will be amber (or yellow); and when a normal speaker is connected properly, the LED will be green.

Each speaker connection made at each speaker terminal can be checked sequentially by simply rotating switch S701. The last position of S701 is the “off” position. Transistor Q701 is connected with its collector to the cathodes of LED D706 and the emitter is connected to ground. Q701 is normally on from receiving a positive bias from +14.4V via R710, when Q701 is on, it permits the LED current flow to serve the purpose of indications. But when switch S701 is set to off after checking all speaker connections, −14.4V is applied to the base of transistor Q701 via resistor R706, S701 pin 10 and pin 1, then through R711. Q701 receives a reversed bias to go into an off state, which obstructs the current flow through LED D706. This shuts off the function of LDS circuit.

What is claimed is:

1. A load detection circuit for determining when (1) a loudspeaker load is properly connected at a set of loudspeaker terminals, (2) a loudspeaker load is improperly connected at the loudspeaker terminals, and (3) no loudspeaker load is connected at the loudspeaker terminals.

2. A load detection circuit according to claim 1 wherein the load detection circuit comprises two operational amplifiers.

3. A load detection circuit according to claim 1 wherein the load detection circuit comprises two light emitting diodes packaged in a single housing, and further wherein one of the two light emitting diodes is a green diode and the other one of the two light emitting diodes is a red diode, the load detection circuit being configured to (1) light the green diode when the loudspeaker load is properly connected at the loudspeaker terminals, (2) light the red diode when the loudspeaker load is improperly connected at the loudspeaker terminals, and (3) light both the green diode and the red diode together when there is no loudspeaker load connected at the loudspeaker terminals.
